(19) United States
(12) Patent Application Publication
(10) Pub. No.: US 2013/0071791 A1
(43) Pub. Date: Mar. 21, 2013

(54) CHARGED PARTICLE BEAM IRRADIATION APPARATUS, CHARGED PARTICLE BEAM DRAWING APPARATUS, AND METHOD OF MANUFACTURING ARTICLE

(71) Applicants: Keiichi Arita, Himeji-shi (JP); Masahito Shinohara, Utsunomiya-shi (JP)

(72) Inventors: Keiichi Arita, Himeji-shi (JP); Masahito Shinohara, Utsunomiya-shi (JP)

(73) Assignee: CANON KABUSHIKI KAISHA, Tokyo (JP)

(21) Appl. No.: 13/612,978

(22) Filed: Sep. 13, 2012

(30) Foreign Application Priority Data
Sep. 21, 2011 (JP) 2011-206557

(51) Int. Cl. H01J 3/08; G03F 7/20; H01J 3/26

(52) U.S. Cl. 430/296; 250/397

(57) ABSTRACT

An irradiation apparatus includes: a measurement device including a shield in which plural apertures are formed, and plural detectors configured to respectively detect plural charged particle beams respectively having passed through the plural apertures; a scanning mechanism configured to perform scanning of the plural beams and the measurement device relative to each other so that the plural beams respectively traverse edges of the plural apertures; and a controller configured to perform control of the scanning mechanism and the measurement device to obtain a characteristic of each beam. The controller is configured to perform the control such that in a period of the scanning, an energy, shielded by the shield, out of an energy of one beam increases with time, while an energy, shielded by the shield, out of an energy of another beam decreases with time.

### BACKGROUND OF THE INVENTION

1. Field of the Invention

The present invention relates to a charged particle beam irradiation apparatus, a charged particle beam drawing apparatus, and a method of manufacturing an article.

2. Description of the Related Art

In a drawing method which uses a plurality of electron beams, it is necessary to periodically measure and correct the characteristics of the electron beams in order to reduce the influence of variations and temporal changes in characteristics of the electron beams. If the diameter or the spot size of each electron beam is sufficiently larger than that of each pixel of a two-dimensional sensor for measuring the characteristics of this electron beam, these characteristics can be directly measured using this sensor. However, in practice, the diameter of each electron beam is as small as several ten nanometers, so the characteristics of such electron beam cannot be directly measured using the above-mentioned sensor.

The use of, for example, a knife edge is effective in measuring such electron beams. In the knife edge method, the characteristics of each electron beam are measured while shielding this electron beam using a knife edge plate formed above the sensor. Hence, the knife edge plate is irradiated with the energy of the shielded electron beam, resulting in a rise in its temperature. When the temperature of the knife edge plate rises, it thermally expands, so an edge position of a knife edge of the knife edge plate changes. In the knife edge method, the amount of shielded electron beam fluctuates during measurement, so the edge position also fluctuates during measurement, leading to degradation in measurement precision.

To reduce the influence of the fluctuations in temperature upon electron beam irradiation, Japanese Patent Laid-Open No. 11-162811 proposes a method of placing a heater on an aperture plate which forms a patterned beam to control so that the sum total of the amount of electron beam irradiation and the amount of heat generated by the heater stays constant. Also, Japanese Patent Laid-Open No. 9-134869 proposes a method of building a heater into a circuit board which controls a blanker, so that the amount of heat generated by the circuit board stays constant. To reduce the difference in temperature between an exposure area irradiated with electron beams and a non-exposure area which is not irradiated with the electron beams, Japanese Patent Laid-Open No. 2000-243696 proposes a method of irradiating the non-exposure area with radiation that does not influence a resist, so that the total energy applied to an object stays constant.

In the methods described in Japanese Patent Laid-Open Nos. 11-162811, 9-134869 and 2000-243696, the fluctuations in temperature can be reduced because the input amount of heat always stays constant. However, as heat is applied to the object not only by the electron beams but also by the heater, the total amount of applied heat increases. This may increase the amounts of position shift of surrounding members due to thermal expansion, and degrade the signal transmission characteristics of a transmission path due to a rise in electric resistance thereof. Further, the use of a heater makes it necessary to add new constituent elements such as a temperature measurement unit, a heater, and a controller, thus complicating the apparatus configuration.

### SUMMARY OF THE INVENTION

The present invention provides, for example, an irradiation apparatus advantageous in terms of measurement precision of a characteristic of a charged particle beam.

The present invention in its one aspect provides an irradiation apparatus which irradiates an object with a plurality of charged particle beams, the apparatus comprising: a measurement device including a shield in which a plurality of apertures are formed, and a plurality of detectors configured to respectively detect the plurality of charged particle beams respectively having passed through the plurality of apertures; a scanning mechanism configured to perform scanning of the plurality of charged particle beams and the measurement device relative to each other so that the plurality of charged particle beams respectively traverse edges of the plurality of apertures; and a controller configured to perform control of the scanning mechanism and the measurement device to obtain a characteristic of each of the plurality of charged particle beams, wherein the controller is configured to perform the control such that in a period of the scanning, an energy, shielded by the shield, out of an energy of one charged particle beam increases with time, while an energy, shielded by the shield, out of an energy of another charged particle beam decreases with time.

Further features of the present invention will become apparent from the following description of exemplary embodiments with reference to the attached drawings.

### BRIEF DESCRIPTION OF THE DRAWINGS

FIG. 1 is a block diagram showing the configuration of a drawing apparatus;

FIGS. 2A to 2C are views for explaining the knife edge method;

FIG. 3 is a graph showing a change in amount of electron beam irradiation during measurement;

FIGS. 4A and 4B are views for explaining measurement according to the related art technique;

FIGS. 5A to 5C are views for explaining measurement according to the first embodiment;

FIGS. 6A to 6C are views for explaining measurement according to the second embodiment;

FIGS. 7A to 7C are views for explaining measurement according to the third embodiment; and

FIG. 8 is a graph for explaining another example of the measurement according to the third embodiment.

### DESCRIPTION OF THE EMBODIMENTS

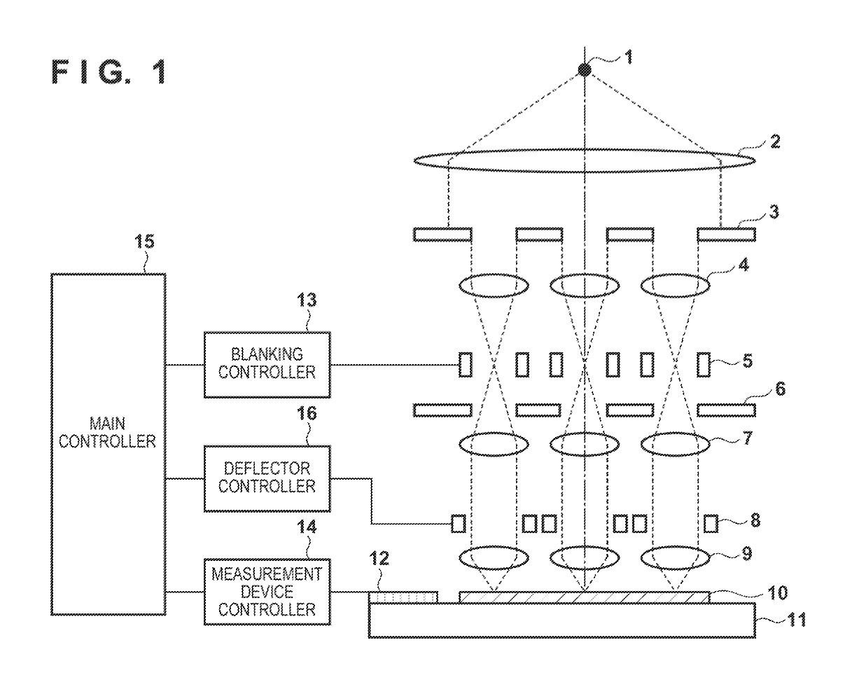

Embodiments of the present invention will be described below with reference to the accompanying drawings. Although the present invention is applicable to an irradiation apparatus which irradiates an object with a plurality of charged particle beams such as electron beams or ion beams, an example in which the present invention is applied to a drawing apparatus which draws a pattern on a substrate with a plurality of electron beams will be described. The configuration of a drawing apparatus which draws with a plurality of electron beams will be described first with reference to a schematic block diagram shown in FIG. 1. An electron gun forms an image of a crossover 1. Using the crossover 1 as a charged particle source, a nearly collimated electron beam is formed by a condenser lens 2. An aperture array 3 is formed by two-dimensionally arranging apertures. A lens array 4 is formed by two-dimensionally arranging electrostatic lenses having the same focal length. A blanker array 5 is formed by two-dimensionally arranging electrostatic blankers capable of individually deflecting electron beams.

The number of electron beams to be projected is controlled by a blanking controller 13 that controls the blanker array 5. The collimated electron beam formed by the condenser lens 2 is divided into a plurality of electron beams by the aperture array 3. The divided electron beams form intermediate images of the crossover 1 at the level of the blanker array 5 via the lens array 4. The electron beams having passed through the blanker array 5 are projected via electromagnetic lenses 7 and 9 onto a substrate 10 or measurement device 12 held on a stage 11. The electron beams having passed through the blanker array 5 are individually deflected by a deflector 8 controlled by a deflector controller 16, so the position of a projected image of each electron beam is determined depending on the amount of deflection by the deflector 8 (the deflection voltage of the deflector). The aperture array 3, lens array 4, blanker array 5, electromagnetic lenses 7 and 9, and deflector 8 constitute a charged particle optical system which emits a plurality of electron beams toward the substrate 10.

The measurement device 12 measures a characteristic of each applied electron beam under the control of a measurement device controller 14. Measurement items may include at least one of the intensity, intensity distribution, and irradiation position of each electron beam. Measurement conditions are calculated by a main controller 15 and selected by making the blanking controller 13 drive the blanker array 5. The measurement result obtained by the measurement device 12 is sent to the main controller 15, which calculates the characteristics of each electron beam. The main controller 15 and measurement device controller 14 constitute a controller which obtains the characteristics of each electron beam from an output of a sensor (detector) of the measurement device 12.

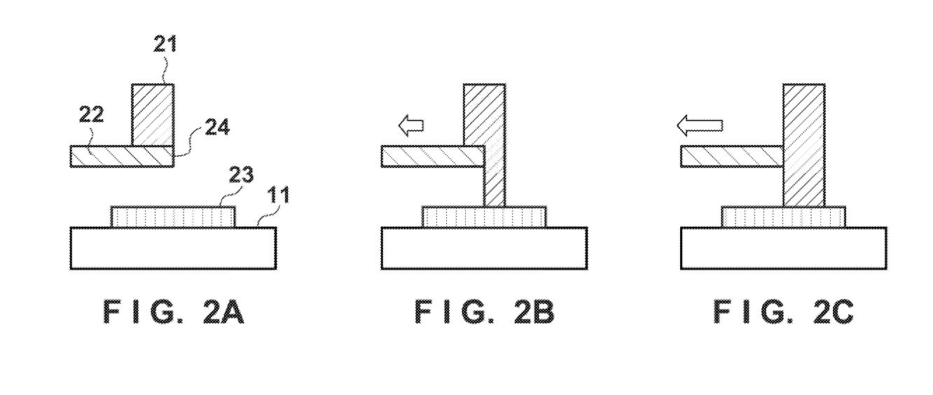

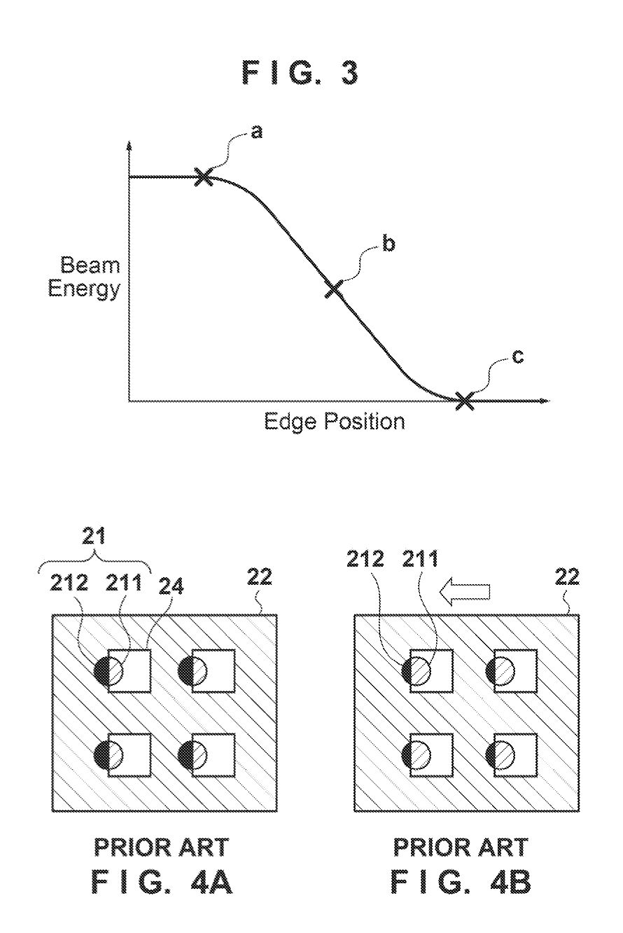

An overview of a knife edge method which performs measurement using a knife edge will be described with reference to FIGS. 2A to 2C and 3. The measurement device 12 includes a knife edge plate (shield or shield member) 22 and measurement sensor (detector) 23. The knife edge plate 22 is a conductive plate and includes a plurality of openings formed in it. The measurement device 12 measures the intensities of electron beams 21 while scanning the electron beams 21 relative to the measurement device 12 so that the electron beams 21 move across edges 24 defining the openings. The direction in which each electron beam 21 is scanned relative to the measurement device 12 is parallel to the surface of the knife edge plate 22. The case wherein one electron beam 21 is measured will be described herein for the sake of simplicity. First, measurement starts while the surface of the knife edge plate 22 is irradiated with the electron beam 21 (FIG. 2A). Measurement is then performed while scanning the knife edge plate 22 and measurement sensor 23 in a direction indicated by arrows (FIGS. 2B and 2C). At this time, the energy of the electron beam 21 applied to the knife edge plate 22 changes, as shown in FIG. 3, so the temperature of the knife edge plate 22 fluctuates.

### First Embodiment

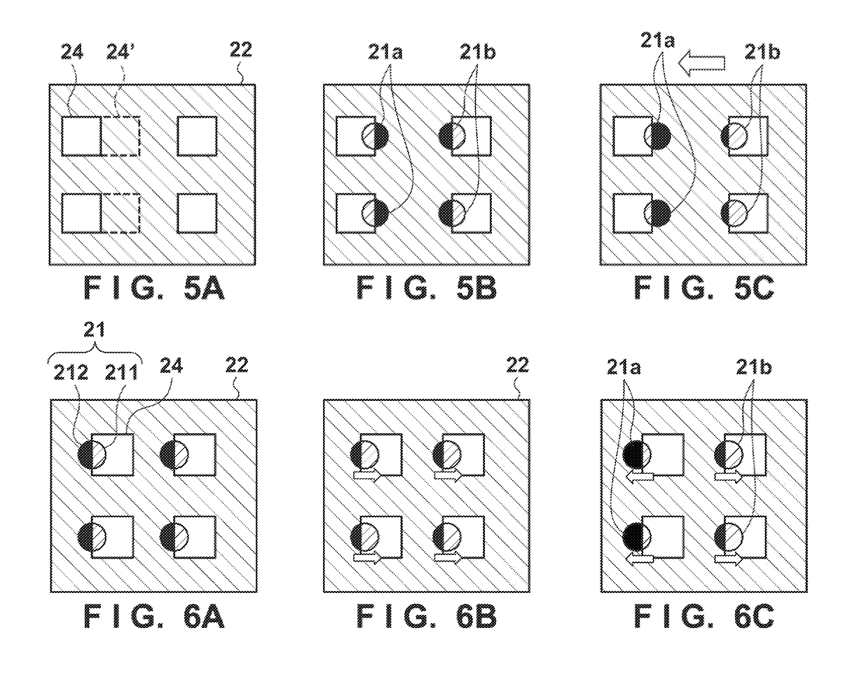

The arrangement of a knife edge plate 22 in a measurement device 12 according to the first embodiment will be described with reference to FIGS. 4A, 4B, and 5A to 5C. The configuration for simultaneous measurement of a plurality of electron beams 21 will be described first. Although an arrangement of 2×2 electron beams will be taken as an example, the present invention is not limited to an arrangement of 2×2 electron beams. FIGS. 4A and 4B show the case wherein four electron beams 21 and four knife edges 24 are arranged in the same pattern. Of the electron beams 21, solid black portions 212 indicate portions which are shielded and reflected by the knife edge plate 22. Also, hatched portions 211 indicate portions detected by a measurement sensor 23 upon passing through the knife edge plate 22. Assuming the total energy of one electron beam 21 as “1”, an energy of 0.5 per beam is applied to the knife edge plate 22 when an edge is positioned at the center of the electron beam 21. Therefore, the total energy of the four electron beams 21 applied to the knife edge plate 22 is 0.5×4=2 (FIG. 4A). The case wherein the edge position moves by ¼ of the diameter of each electron beam 21 will be considered next. In this case, the area of the portion 212 applied to the knife edge plate 22 is 26% per beam. As a result, the total energy of the four electron beams 21 applied to the knife edge plate 22 decreases to about a half, that is, 0.26×4=1.04 (FIG. 4B).

The arrangement of the knife edge plate 22 according to the first embodiment will be described below with reference to FIGS. 5A to 5C. The knife edge 24 is formed by shifting the position of a knife edge 24′ in the prior art by an amount corresponding to one edge (FIG. 5A). The four electron beams 21 are formed by a plurality of (two in FIGS. 5B and 5C) combinations of two electron beams 21a and 21b guided to be adjacent to each other in the scanning direction of each electron beam. As in the related art technique, assuming the total energy of one electron beam 21 as “1”, the areas of the four electron beams 21 applied to the knife edge plate 22 are all 50% when an edge is present at the center of each electron beam 21. Therefore, the total energy of the four electron beams 21 applied to the knife edge plate 22 in that case is 0.5×4=2 (FIG. 5B). The case wherein the edge position moves by ¼ of the diameter of each electron beam will be considered next. The area of one, right electron beam 21b applied to the knife edge plate 22 decreases to 26%, as in the related art technique, while the area of the other, left electron beam 21a increases to 74% (FIG. 5C). As a result, the total energy applied to the knife edge plate 22 can be maintained at a constant value of 0.26×2+0.74×2=2 during the period in which at least one of the four electron beams at least partially passes through the aperture.

In the first embodiment, the electron beams 21a and 21b having energies which change by different amounts upon shielding by the knife edge plate 22 when they are scanned are guided to be adjacent to each other and used as one set of electron beams. However, the electron beams 21a and 21b need not always be guided to be adjacent to each other. It is only necessary to make each of a plurality of electron beams belong to a first or second group so that the electron beams in the first group and the electron beams in the second group have energies which change by different amounts upon shielding by the knife edge plate 22 when they are scanned. The use of the knife edge plate 22 according to the first embodiment allows accurate measurement based on the knife edge method by reducing fluctuations in temperature which depend on the measurement position of each electron beam.

### Second Embodiment

An electron beam deflection control method in the second embodiment will be described with reference to FIGS. 6A to 6C. As in the first embodiment, when an edge is present at the center of each electron beam 21, a total energy of 2 is applied to a knife edge plate 22 (FIG. 6A). The case wherein each electron beam 21 is deflected by ¼ of its diameter using the conventional measurement method which deflects all the electron beams 21 in the same direction will be considered next. The total energy applied to the knife edge plate 22 decreases to about a half, that is, 0.26×4=1.04, as in the related art technique (FIG. 6B).

In the second embodiment, measurement is performed upon deflection of adjacent electron beams 21a and 21b in different directions. Although the electron beams 21a and 21b are deflected in opposite directions as an example, the present invention is not limited in terms of the directions in which they are deflected. When the edge position moves by ¼ of the diameter of each electron beam, the area of the right electron beam 21b applied to the knife edge plate 22 decreases to 26%, as in the related art technique. However, the area of the left electron beam 21a applied to the knife edge plate 22 increases to 74% (FIG. 6C). As a result, the total energy of the four electron beams 21 applied to the knife edge plate 22 can be maintained at a constant value of 0.26×2+0.74×2=2. The use of the deflection control method according to the second embodiment allows accurate measurement based on the knife edge method by reducing fluctuations in temperature which depend on the measurement position of each electron beam.

### Third Embodiment

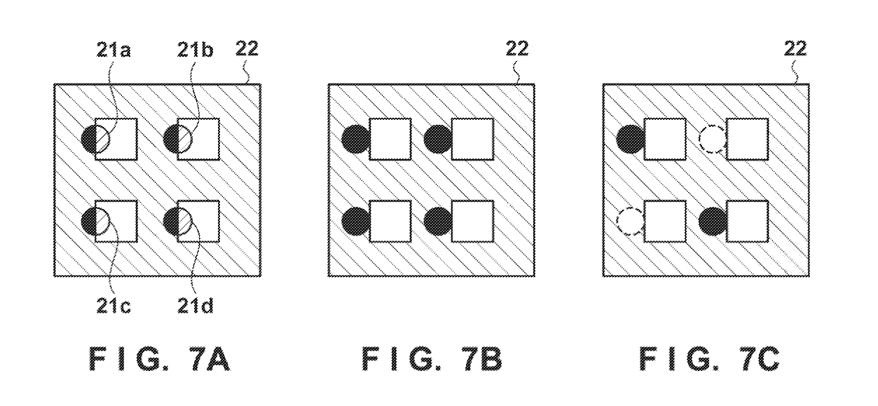

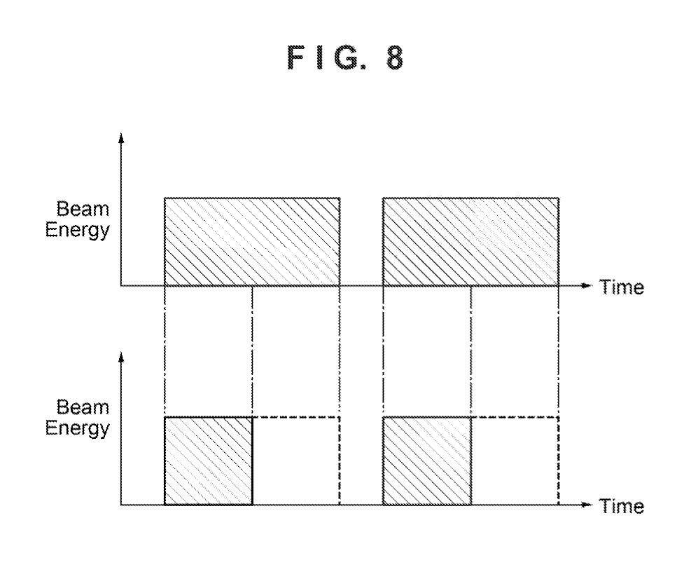

A method of controlling the number or irradiation time of electron beams for irradiation according to the third embodiment will be described with reference to FIGS. 7A to 7C and 8. Although the case wherein the same beam energy as in the first and second embodiments is applied to a knife edge plate will be described as an example, the present invention is not limited in terms of energy. In the first and second embodiments, the energy applied to the knife edge plate during measurement is a half of the overall beam energy (FIG. 7A). FIG. 7B shows a non-measurement state. At this time, since all of four electron beams 21a to 21d are applied to a knife edge plate 22, the total energy applied to the knife edge plate 22 is 4, resulting in fluctuations in temperature. In the third embodiment, a half of the four electron beams 21 is turned off to maintain the total energy at a half of the overall beam energy, thereby reducing fluctuations in temperature (FIG. 7C). Alternatively, the total energy may be controlled by shortening the irradiation times of all of the four electron beams to a half, as shown in FIG. 8. The use of the above-mentioned control method allows accurate measurement by reducing fluctuations in energy applied to the knife edge plate 22 even in a non-measurement state.

Embodiments of the present invention have been described above by taking as an example a drawing apparatus which draws on a substrate with a plurality of charged particle beams. However, the present invention is not limited to a drawing apparatus, and is applicable to other charged particle beam apparatuses which use a plurality of charged particle beams, such as an electron microscope or an electronic distance measurement apparatus.

[Method of Manufacturing Article]

A method of manufacturing an article according to an embodiment of the present invention is suitable for manufacturing an article including a microdevice such as a semiconductor device or an element having a microstructure. This method can include a step of forming a latent image pattern on a photosensitive agent, applied on a substrate, using the above-mentioned drawing apparatus (a step of drawing on the substrate), and a step of developing the substrate having the latent image pattern formed on it in the forming step. This method can also include subsequent known steps (for example, oxidation, film formation, vapor deposition, doping, planarization, etching, resist removal, dicing, bonding, and packaging). The method of manufacturing an article according to this embodiment is more advantageous in terms of at least one of the performance, quality, productivity, and manufacturing cost of an article than the conventional method.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-206557 filed Sep. 21, 2011, which is hereby incorporated by reference herein in its entirety.

What is claimed is:

1. An irradiation apparatus which irradiates an object with a plurality of charged particle beams, the apparatus comprising:
a measurement device including a shield in which a plurality of apertures are formed, and a plurality of detectors configured to respectively detect the plurality of charged particle beams respectively having passed through the plurality of apertures;
a scanning mechanism configured to perform scanning of the plurality of charged particle beams and the measurement device relative to each other so that the plurality of charged particle beams respectively traverse edges of the plurality of apertures; and
a controller configured to perform control of the scanning mechanism and the measurement device to obtain a characteristic of each of the plurality of charged particle beams,
wherein the controller is configured to perform the control such that in a period of the scanning, an energy, shielded by the shield, out of an energy of one charged particle beam increases with time, while an energy, shielded by the shield, out of an energy of another charged particle beam decreases with time.

2. The apparatus according to claim 1, wherein
each of the plurality of charged particle beams belongs to one of a first group and a second group, and
the controller is configured to perform the control such that in the period of the scanning, an energy, shielded by the shield, out of an energy of charged particle beams belonging to the first group, increases with time, while an energy, shielded by the shield, out of an energy of charged particle beams belonging to the second group decreases with time.

3. The apparatus according to claim 1, wherein the controller is configured to perform the control such that the scanning is performed in one direction, and the plurality of apertures are arranged in the shield so that in the period of the scanning, an energy, shielded by the shield, out of an energy of the one charged particle beam increases with time, while an energy, shielded by the shield, out of an energy of the other charged particle beam decreases with time.

4. The apparatus according to claim 1, further comprising:
a deflector configured to individually deflect the plurality of charged particle beams,
wherein the controller is configured to cause the deflector to deflect the one charged particle beam and the other charged particle beam in respective directions different from each other so that in the period of the scanning, an energy, shielded by the shield, out of an energy of the one charged particle beam increases with time, while an energy, shielded by the shield, out of an energy of the other charged particle beam decreases with time.

5. The apparatus according to claim 1, wherein the characteristic includes at least one of an intensity, an intensity distribution, and an irradiation position.

6. The apparatus according to claim 1, wherein the controller is configured to perform the control such that in a sum period of the period of the scanning and a period in which the shield shields all of the plurality of charged particle beams, an energy, shielded by the shield, out of energy of the plurality of charged particle beams does not fluctuate with time.

7. The apparatus according to claim 6, further comprising:
a charged particle optical system configured to generate the plurality of charged particle beams,
wherein the controller is configured to control, during the period in which the shield shields all of the plurality of charged particle beams, at least one of number and irradiation time of charged particle beams with which the charged particle optical system irradiates the shield.

8. A drawing apparatus which performs drawing on a substrate with a plurality of charged particle beams, the apparatus comprising:
an irradiation apparatus configured to irradiate the substrate with the plurality of charged particle beams,
the irradiation apparatus including:
a measurement device including a shield in which a plurality of apertures are formed, and a plurality of detectors configured to respectively detect the plurality of charged particle beams respectively having passed through the plurality of apertures;
a scanning mechanism configured to perform scanning of the plurality of charged particle beams and the measurement device relative to each other so that the plurality of charged particle beams respectively traverse edges of the plurality of apertures; and
a controller configured to perform control of the scanning mechanism and the measurement device to obtain a characteristic of each of the plurality of charged particle beams,
wherein the controller is configured to perform the control such that in a period of the scanning, an energy, shielded by the shield, out of an energy of one charged particle beam increases with time, while an energy, shielded by the shield, out of an energy of another charged particle beam decreases with time.

9. A method of manufacturing an article, the method comprising:
performing drawing on a substrate using a drawing apparatus;
developing the substrate on which the drawing has been performed; and
processing the developed substrate to manufacture the article,
wherein the drawing apparatus performs the drawing on the substrate with a plurality of charged particle beams, the apparatus including an irradiation apparatus configured to irradiate the substrate with the plurality of charged particle beams,
the irradiation apparatus including:
a measurement device including a shield in which a plurality of apertures are formed, and a plurality of detectors configured to respectively detect the plurality of charged particle beams respectively having passed through the plurality of apertures;
a scanning mechanism configured to perform scanning of the plurality of charged particle beams and the measurement device relative to each other so that the plurality of charged particle beams respectively traverse edges of the plurality of apertures; and
a controller configured to perform control of the scanning mechanism and the measurement device to obtain a characteristic of each of the plurality of charged particle beams,
wherein the controller is configured to perform the control such that in a period of the scanning, an energy, shielded by the shield, out of an energy of one charged particle beam increases with time, while an energy, shielded by the shield, out of an energy of another charged particle beam decreases with time.
